(19) United States
(12) Patent Application Publication
(10) Pub. No.: US 2024/0124741 A1
(43) Pub. Date: Apr. 18, 2024

(54) POLY(3,4-ETHYLENEDIOXYTHIOPHENE) POLYSTYRENE SULFONATE AND PHENYLALANINE COMPOSITE FILMS

(71) Applicant: Ramesh Adhikari, Hamilton, NY (US)

(72) Inventor: Ramesh Adhikari, Hamilton, NY (US)

(73) Assignee: COLGATE UNIVERSITY, HAMILTON, NY (US)

(21) Appl. No.: 18/379,707

(22) Filed: Oct. 13, 2023

Related U.S. Application Data
(60) Provisional application No. 63/415,787, filed on Oct. 13, 2022.

(51) Int. Cl. C09D 181/08

(52) U.S. Cl. CPC C09D 181/08

(57) ABSTRACT

Conductive films formed from composites of phenylalanine and poly(3,4-ethylenedioxythiophene) doped with poly(styrenesulfonate) (PEDOT:PSS). The composite films formed by introducing aromatic amino acid phenylalanine in PEDOT:PSS improved the conductivity of the film to about 594 S/cm, a 400% increment compared to the conductivity of a pristine PEDOT:PSS film of about 1.5 S/cm. The conductivity can be tuned by adding a varying amount of phenylalanine in PEDOT:PSS. By further processing these composite films by treating them with methanol followed by annealing, conductivity of over 2200 S/cm can be achieved. In addition to increased conductivity, the composite films also have higher optical transmissivity compared to a native PEDOT:PSS polymer film with the composite thin film achieving transmittance of over 97%.

### CROSS-REFERENCE TO RELATED APPLICATIONS

The present invention application claims priority to U.S. Provisional Application No. 63/415,787 on Oct. 13, 2022, hereby incorporated by reference in its entirety.

### BACKGROUND OF THE INVENTION

### 1. Field of the Invention

The present invention relates to conductive polymers, and more particularly, to a composite polymer film having improved conductivity and optical transmissivity compared to a native polymer film.

### 2. Description of the Related Art

Intrinsically conducting polymer complex poly(3,4-ethylenedioxythiophene) doped with poly(styrenesulfonate) (PEDOT:PSS) is widely used in various electronic applications such as active material for organic electrochemical transistors (OECT), electrodes for supercapacitors, and photovoltaic cells owing to their properties such as chemical stability, ease of processing, high transparency as thin films, and commercial availability. In addition to these properties, due to the flexibility of PEDOT:PSS films being a mixed electron and ion conductor, it is also currently being studied as sensing surfaces and electrodes for bioelectronic devices.

Despite its versatility, the widespread application of PEDOT:PSS in electronic devices is limited due to two major challenges. The conductivity of PEDOT:PSS is lower than other commercially available conductors such as indium tin oxide (ITO) or metals. In addition, the use of PEDOT:PSS specifically in bioelectronic devices is also limited by its biocompatibility. To address the first challenge, various research has been carried out to improve the conductivity of PEDOT:PSS. PEDOT:PSS is composed of PEDOT units which are small aggregates with molecular weights of about 1000 g/mol while PSS units are large with molecular weights of about 400,000 g·mol. In a PEDOT:PSS film, hydrophobic conducting PEDOT oligomers aggregate along the hydrophilic non-conducting PSS chains that coil to form pancake-like granular structures within which charge transport is promoted by pi-stacking of PEDOT units while charges need to overcome potential associated with the charge transport across the grains. This transport can be promoted by using various physical and chemical methods that alter the chemical properties or physical morphology of the PEDOT:PSS film. Some examples of such physical methods are thermal treatment which increases the grain sizes or UV radiation which linearizes the PSS coil and hence reduces charge trapping. On the other hand, the conductivity of PEDOT:PSS can also be improved by chemically treating PEDOT:PSS with polar organic compounds such as dimethyl sulfoxide (DMSO) or its derivative, ethylene glycol (EG), strong acids, ionic liquids, surfactants, and salts. The improvement in conductivity of PEDOT:PSS with these chemical treatments has been attributed to mechanisms such as charge screening to lower columbic interaction between PEDOT and PSS, and phase separation between PEDOT and PSS and hence improving charge transport along PEDOT due to removal of excess PSS along the charge transport pathways.

To address the second challenge, various work has been done to improve the biocompatibility of PEDOT:PSS by introducing biological materials in PEDOT:PSS or the PEDOT matrix itself. Conducting polymers can either be functionalized with biological materials or these biological materials can be introduced as dopants in the conducting polymer matrix. Various bioderived materials such as dextran sulfate and xanthan gum can be used as PEDOT dopants, replacing PSS, which result in the formation of conductive biocompatible films. Other bioderived molecules such as pectin, sulfated cellulose, and DNA have also been used as PEDOT dopants. Conductivity of PEDOT:PSS films can also be improved by introducing bioderived molecules such as DMSO or sorbito which are acquired by processing biological systems. However, these additives either retain or only slightly increase the conductivity of the films thus created and can involve complicated or expensive manufacturing processes. Accordingly, there is a need in the art for a highly conductive film that can be easily manufactured into films for use in electronic and bioelectronic applications.

### BRIEF SUMMARY OF THE INVENTION

The present invention provides a highly conductive film formed from composites of phenylalanine and poly(3,4-ethylenedioxythiophene) doped with polystyrene sulfonate (PEDOT:PSS). Phenylalanine self-assembles in water, which can be dropcast on a substrate to form a film of mesoscale fibrils and shows no electronic conductance. When the phenylalanine solution in water is mixed with a PEDOT:PSS solution, however, the resulting composite film can have conductivity values up to two orders of magnitude higher than pristine PEDOT:PSS film. More specifically, composite films formed with the aromatic amino acid phenylalanine in PEDOT:PSS can improve the conductivity of the film to about 594 S/cm, a 400% increment compared to the conductivity of a pristine PEDOT:PSS film of about 1.5 S/cm. In addition, the conductivity can be tuned by adding a varying amount of phenylalanine in PEDOT:PSS. Upon further treatment of the film with methanol followed by annealing, the conductivity of the composite thin film can be increased to more than 2200 S/cm while similarly treated 100% PEDOT:PSS film conductivity increased to slightly more than 1000 S/cm. Composites of bioderived amino acids with conducting polymers according to the present invention can thus be prepared in a cost-effective and environmentally friendly manner for uses such as biocompatible electrodes for bioelectronics.

In a first aspect, the invention comprises a composite film that is formed from an amount of phenylalanine and an amount of poly(3,4-ethylenedioxythiophene) doped polystyrene sulfonate (PEDOT:PSS). The amount of phenylalanine may be between 10 and 90 percent by volume of the composite film. The amount of phenylalanine may be 50 percent by volume of the composite film. The composite film may be characterized by a conductivity of over 500 siemens per centimeter. The composite film may have an optical transmissivity that is greater than a film consisting of poly(3,4-ethylenedioxythiophene) doped polystyrene sulfonate. The film may have been treated with methanol. The film may have been annealed.

In another aspect, the invention comprises a method of making a composite film, comprising the step of drop casting a solution comprising an amount of poly(3,4-ethylenedioxythiophene) doped polystyrene sulfonate (PEDOT:PSS) and an amount of phenylalanine. The amount of phenylalanine may be between 10 and 90 percent by volume of the composite film. The amount of phenylalanine may be 50 percent by volume of the composite film. The composite film may be characterized by a conductivity of over 500 siemens per centimeter. The composite film may have an optical transmissivity that is greater than a film consisting of poly(3,4-ethylenedioxythiophene) doped polystyrene sulfonate. The method may further comprise the step of treating the film with methanol. The method may further comprise the step of treating the film with methanol followed by annealing to further improve the conductivity of the composite film to over 2000 siemens per centimeter while significantly improving the transmittivity of the film compared to the film composed of only PEDOT:PSS.

### BRIEF DESCRIPTION OF THE SEVERAL VIEWS OF THE DRAWING(S)

The present invention will be more fully understood and appreciated by reading the following Detailed Description in conjunction with the accompanying drawings, in which:

FIG. 1 is a schematic of a) Molecular structures of PEDOT:PSS, phenylalanine and alanine used in this study and b) Schematic of preparation of PEDOT:PSS-Phenylalanine Films.

FIG. 2 is a series of optical images of the dry films dropcasted onto a substrate with concentration of phenylalanine a) 0% b) 10% c) 20% d) 30% e) 40% f) 50% g) 60% h) 70% i) 80% j) 90% k) 100%.

FIG. 3 is a pair of graphs of a) Current-voltage (IV) responses of films composing of volumetric mixture of PEDOT:PSS and phenylalanine; and b) The IV response in a semi-log graph.

FIG. 4 is a graph of the conductivity of PEDOT:PSS-amino acid composite film with an increasing percentage of phenylalanine (blue) and alanine (red). 0% indicates films with no amino acid i.e. with 10% PEDOT:PSS.

FIG. 5 is a pair of graphs of current-voltage (IV) response of PEDOT:PSS-Alanine (PPA) films.

FIG. 6 is a series of graphs of the electrochemical impedance spectroscopy (EIS) measurements: Nyquist plot of a) PEDOT:PSS film, and b) film with 50% volumetric mixture of PEDOT:PSS and phenylalanine. Arrows indicate the direction from the high-frequency to low-frequency measurements. Bode plot of with c) the magnitude of impedance and d) phase of impedance as a function of frequency.

FIG. 7 is a pair of graphs of a Nyquist plot of PEDOT:PSS-Phenylalanine (PPP) films with the concentration of phenylalanine from a) 0-30% and b) 40-90%. Corresponding equivalent circuits that fit the plot are presented as inset in each of the charts.

FIG. 8 is a series of Bode plot of films with (a,c) 0-30% phenylalanine and (b,d) 40-90% phenylalanine.

FIG. 9 is a series of graphs of EIS measurements of PPA films with a) Nyquist plot and b) Bode plot.

FIG. 10 is a series of images of films according to the present invention, including a-c) SEM images (scale bars: 50 μm), (d-f) AFM topographical images (scan size 10 um²), and (g-i) CP-AFM images of PPP films with 0%, 50% and 90% phenylalanine, respectively. Scale bars for CP-AFM are g) 400 nm, h) 200 nm, and i) 600 nm, while the corresponding topographical AFM images are shown as inset.

FIG. 11 is a series of I) SEM and II) AFM images of PPP films with concentration of alanine a) 0% b) 10% c) 20% d) 30% e) 40% f) 50% g) 60% h) 70% i) 80% j) 90%.

FIG. 12 is a pair of images of current maps on (a) a globule and (b) on a flat region outside globule.

FIG. 13 is a pair of graphs of the roughness of the a) PPP and b) PPA film surfaces.

FIG. 14 is a graph of the XRD spectra of PPP films.

FIG. 15 is a series of I) SEM and II) AFM images of PPA films with concentration of alanine a) 0% b) 10% c) 20% d) 30% e) 40% f) 50% g) 60% h) 70% i) 80% j) 90%.

FIG. 16 is a graph of the transmittance of composite films of 50 vol % PEDOT:PSS and 50 vol % phenylalanine compared to that of 100% PEDOT:PSS thin films after applying 3 coats and 5 coats.

FIG. 17 is a graph of the transmittance of the thin films prepared with 100% PEDOT:PSS of various thicknesses compared to the films with 50 vol % phenylalanine solution (red) and 50 vol % PEDOT:PSS solution. Both of these films were treated with methanol.

FIG. 18 is a graph of the transmittance of the methanol treated thin films with 100% PEDOT:PSS of various thicknesses compared to the composite films with 50 vol % phenylalanine solution and 50 vol % PEDOT:PSS solution. These films were annealed at indicated temperatures after methanol treatment which resulted in improvement of transmittance

FIG. 19 is a graph of the conductivity of 100% PEDOT:PSS thin films compared to that of composite thin film formed from 50 vol % phenylalanine solution and 50 vol % PEDOT:PSS. followed by methanol treatment and then annealing.

### DETAILED DESCRIPTION OF THE INVENTION

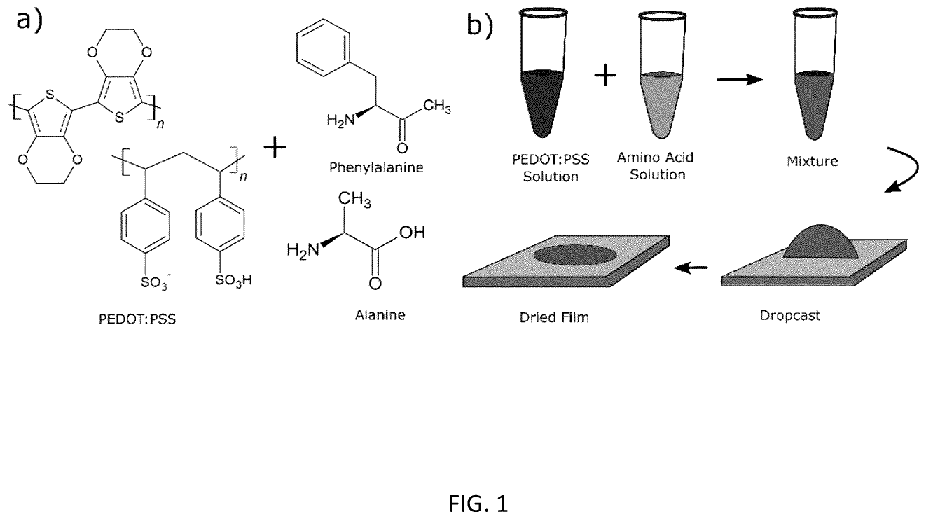

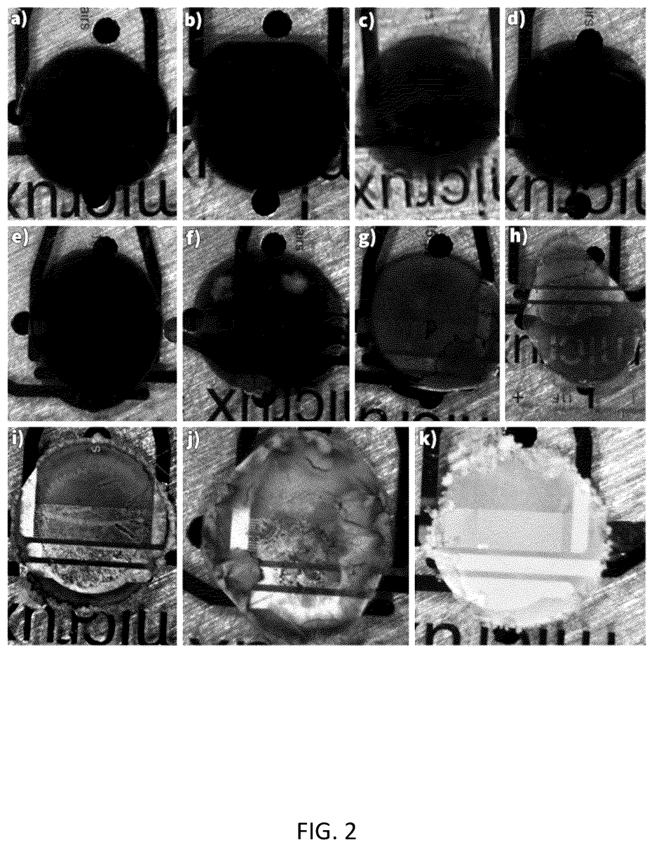

Referring to the figures, wherein like numerals refer to like parts throughout, there is seen in FIG. 1 a schematic of the molecular structure of composites of phenylalanine and poly(3,4-ethylenedioxythiophene) doped with polystyrene sulfonate (PEDOT:PSS) according to the present invention as well as an exemplary approach for preparing such films.

Referring to FIG. 1, films of amino acids-PEDOT:PSS composites were prepared by drop-casting a solution that contained the mixture of varying volumetric ratios of PEDOT:PSS solution and L-phenylalanine (Phe) solution in water. The details of the preparation process are discussed below. Ten different solutions were prepared with the content of solution ranging from volumetric percentage of 100 vol % PEDOT:PSS to 0 vol % PEDOT:PSS with the complementary portion of the solution being that of phenylalanine or alanine. The drop-casted solution was then left to dry at ambient room temperature and humidity which resulted in the formation of thin circular films with thickness of anywhere from 6 micrometers to 10 micrometers and different levels of coloration due to the difference in the content of PEDOT:PSS, as seen in FIG. 2. Table 1 below provides resistance values derived from DC and AC measurements for the films in a week and a month after the films were drop-casted.

TABLE 1

| Sample (vol. | | | | |
|---|---|---|---|---|
| % of L-Phe | | | | |
| in PEDOT: | | | | |
| PSS/L-Phe | DC Resistance (Ω) | | AC Resistance (Ω) | |
| composite) | 1 week | 1 month | 1 week | 1 month |
| 0 | 3663 | 2564 | 3874 | 2632 |
| 10 | 810 | 654 | 820 | 728 |
| 20 | 293 | 293 | 321 | 321 |
| 30 | 115 | 112 | 129 | 122 |
| 40 | 42 | 43 | 45 | 47 |
| 50 | 17 | 17 | 17 | 19 |
| 60 | 55 | 62 | 62 | 68 |
| 70 | 87 | 100 | 98 | 111 |
| 80 | 73 | 93 | 82 | 100 |
| 90 | 91 | 100 | 102 | 110 |

For scaling up this process, however, spin coating is preferred so that uniform thin films can be constructed on desired surfaces. Therefore, measurements of the conductivity and transmittivity have also been carried out by fabricating thin films of thickness in the range of tens of nanometers.

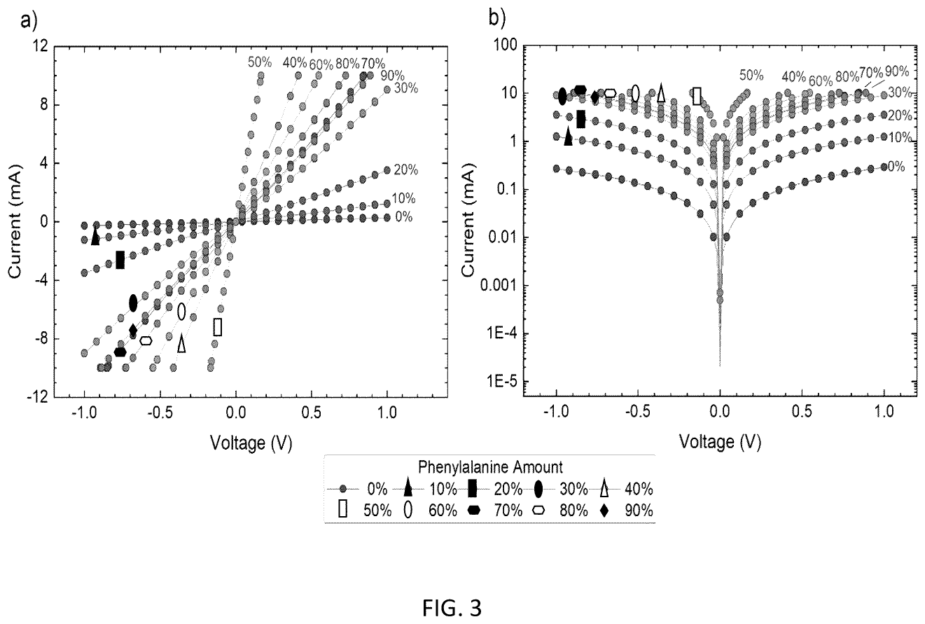

Current-voltage (IV) measurements of the films were carried out by sweeping voltage across the interdigitated electrodes and then recording the resulting current. The resulting IV curves were mostly linear and non-hysteretic, indicating the Ohmic behavior of the films as seen in FIG. 3A. The conductance of the film increased even when just 10 vol % of phenylalanine solution is introduced to the film. However, the current responses were higher for PEDOT:PSS films with even higher concentrations of phenylalanine. In fact, the current response of the films with higher concentrations of phenylalanine was orders of magnitude higher than for the pure PEDOT:PSS film, or the films with lower concentrations of phenylalanine even for small applied voltages, as seen in FIG. 3B. Once the volumetric composition of the phenylalanine solution in the PEDOT:PSS solution exceeded 50 vol %, the conductance started to decrease, but still stayed much higher compared to that of pure PEDOT:PSS films. As seen in FIG. 3B, there is no hysteresis suggesting that the conduction through the films is purely electronic (as opposed to ionic or mixed electronic-ionic).

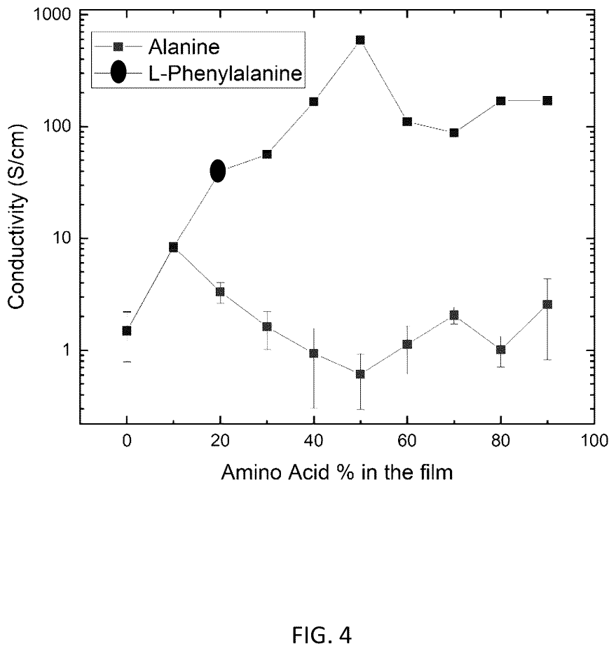

By measuring the thickness of the film and taking the electrode gap into account, the conductivity of the PEDOT:PSS-phenylalanine (PPP) composite films was calculated, as seen in FIG. 4. The conductivity of PEDOT film with no phenylalanine was 1.5±0.7 S/cm. This value is similar to the PEDOT:PSS film conductivity values reported elsewhere. However, the conductivity of the PPP films for all concentrations of phenylalanine was significantly higher than that of pure PEDOT:PSS film with the highest conductivity of 594±1.2 S/cm recorded for the PPP film with 50 vol % phenylalanine solution, which is about 400 times larger than the conductivity of pristine PEDOT:PSS film. The conductivity values of these films rise in almost linear fashion in the semi-log graph till the concentration of phenylalanine solution reaches 50 vol % suggesting that the increasing amount of phenylalanine results in exponential growth in the conductivity of the film. Once the concentration of phenylalanine is higher, then conductivity decreases and then levels off with the conductivity of PPP film made from 90 vol % phenylalanine solution being 170±1.9 S/cm which is still about 100 times higher than the PEDOT:PSS film.

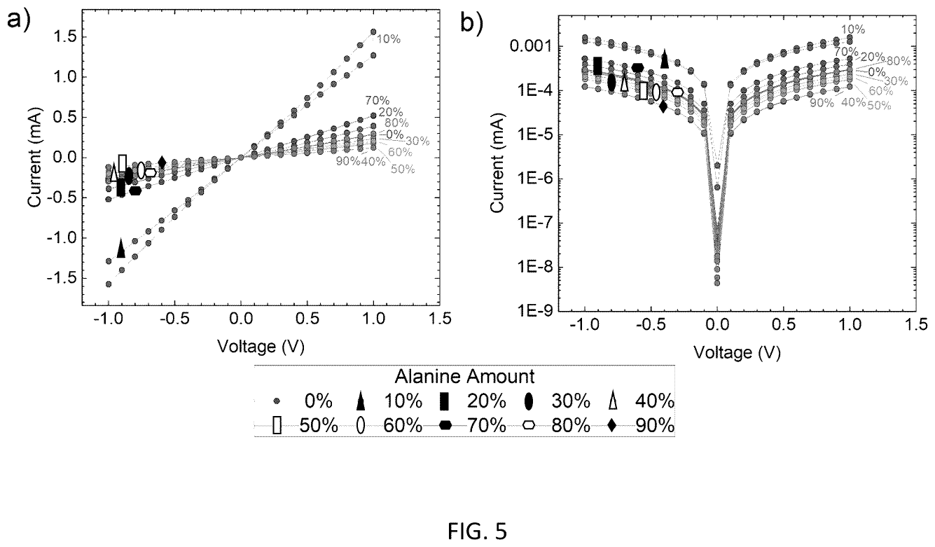

The measurements were repeated on films composed of a mixture of PEDOT:PSS solution with an alanine solution. Alanine is analogous to phenylalanine with the only difference in their molecular structure being the lack of aromatic residue in alanine. Resulting PEDOT:PSS-alanine (PPA) films also demonstrated linear current response to sweeping voltage as seen in FIG. 5. The conductivity of these films were measured as well, as seen in FIG. 4. After a slight increase in the conductivity, it appears that the conductivity of the PPA films decreases as the concentration of alanine is increased before leveling off. The dramatic improvement in the conductivity of the PEDOT:PSS films with increasing concentration of an amino acid that possesses an aromatic site and the decline of the conductivity with an increasing amount of amino acid deficient in aromatic site suggests that the aromatic residues in phenylalanine are, in some way or form, responsible for promoting efficient charge transport through the PPP system.

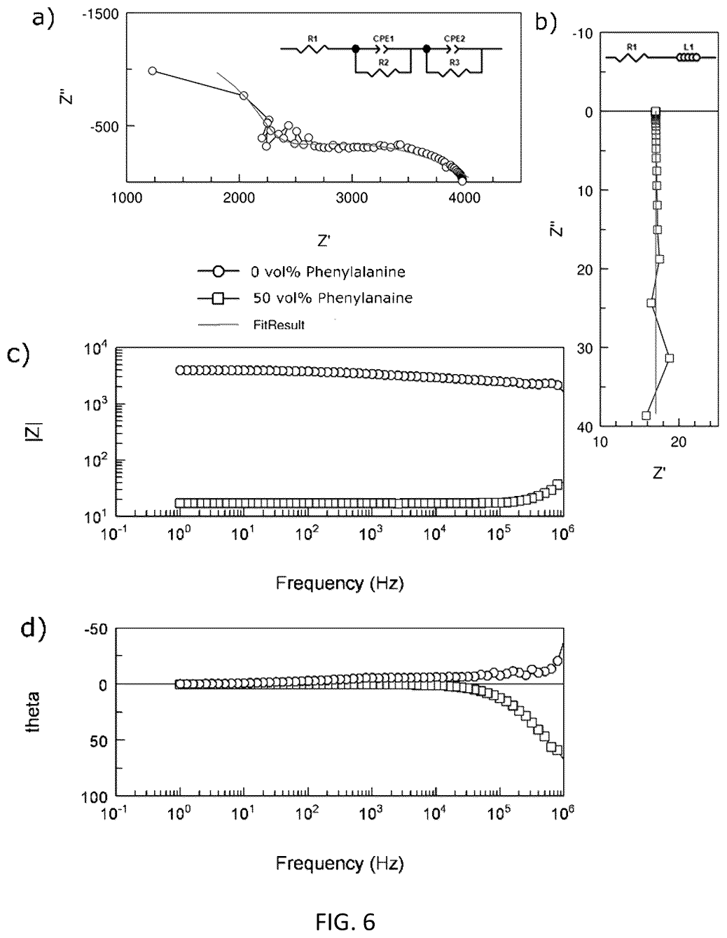

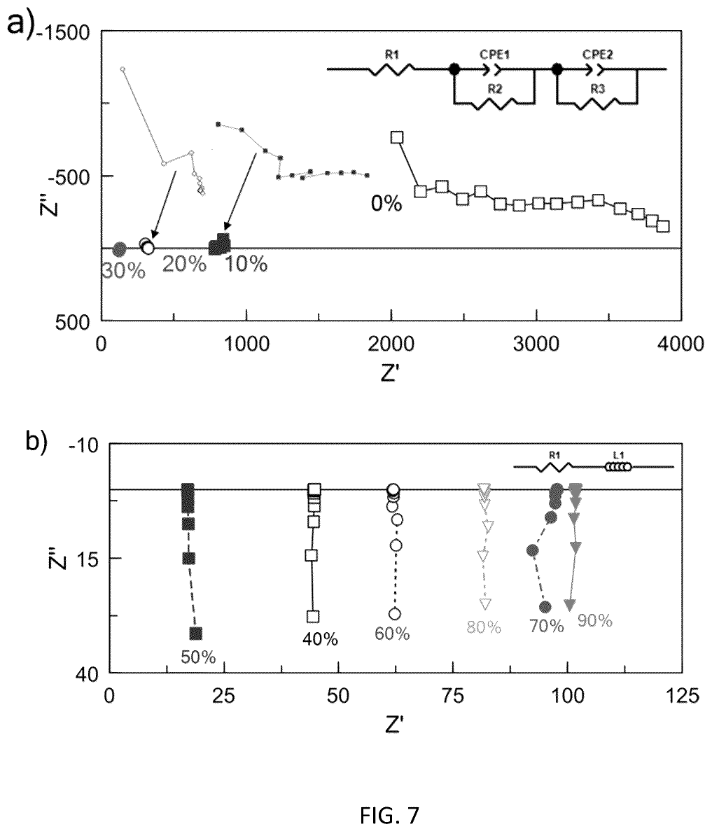

To further explore the charge conduction mechanisms in these films, electrochemical impedance spectroscopy (EIS) measurement involving applying time-varying voltage (V(t) with a small amplitude across the sample while recording the current response (I(t)) were performed. This can then be used to calculate the impedance of the system, which comprises of real and imaginary components as: Z=V(t)/I(t)=Z′+iZ″. The resulting Nyquist plot of the impedance of the pure PEDOT:PSS film demonstrated behavior that can be thought of a combination of two semicircles with different time constants, as seen in FIG. 6A. This data can be fit with an equivalent circuit comprising two modified Randles circuits in series that include a constant phase element (CPE) in addition to the resistor component. Based on the fit values of CPE and the resistors, the time constant (τ=RC) for the semicircle towards the higher frequency is 2×10⁻¹¹ s and for the semicircle towards the lower frequency regime was found to be about 7×10⁻² s, suggesting that there are two different charge transport processes in the film with significantly varying timescales. When phenylalanine is introduced in the PEDOT:PSS and the concentration is increased, the two timescale process evolves into one with decreasing impedance, see FIG. 7, with the time constant in the range of 10⁻⁷ s for 20 vol % phenylalanine film. When the phenylalanine content reaches 30 vol %, the Nyquist plot collapses into a point on the real impedance axis suggesting that the capacitive component in charge transport is eliminated and the film becomes purely resistive.

In the films with an even higher concentration of phenylalanine, the Nyquist plot of the films demonstrates the conduction mechanism in which the resistance is coupled with the inductor instead of the capacitor. This is indicated by the Nyquist plot with the positive imaginary impedance which was prevalent in all the films with phenylalanine concentration of 40 vol % or higher, see FIG. 7. For instance, the Nyquist plot of the film with 50 vol % PEDOT:PSS, the film with the highest conductivity, demonstrated a high-frequency inductive tail and which intersected with the horizontal real impedance axis for the lower frequencies, see FIG. 6, with the time constant (τ=L/R) associated with this transport process to be around 10⁻⁷ s as well.

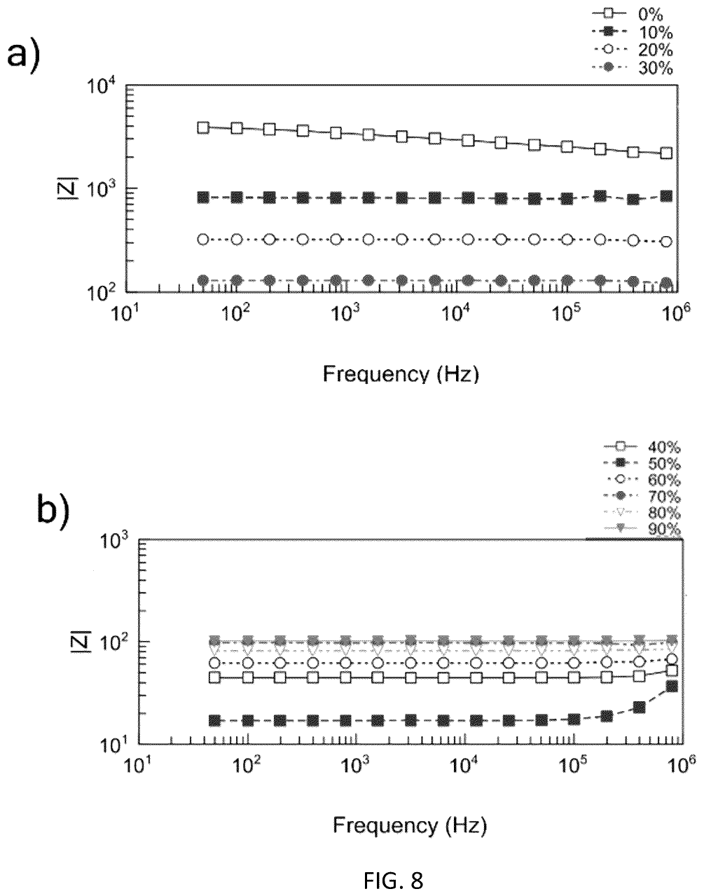

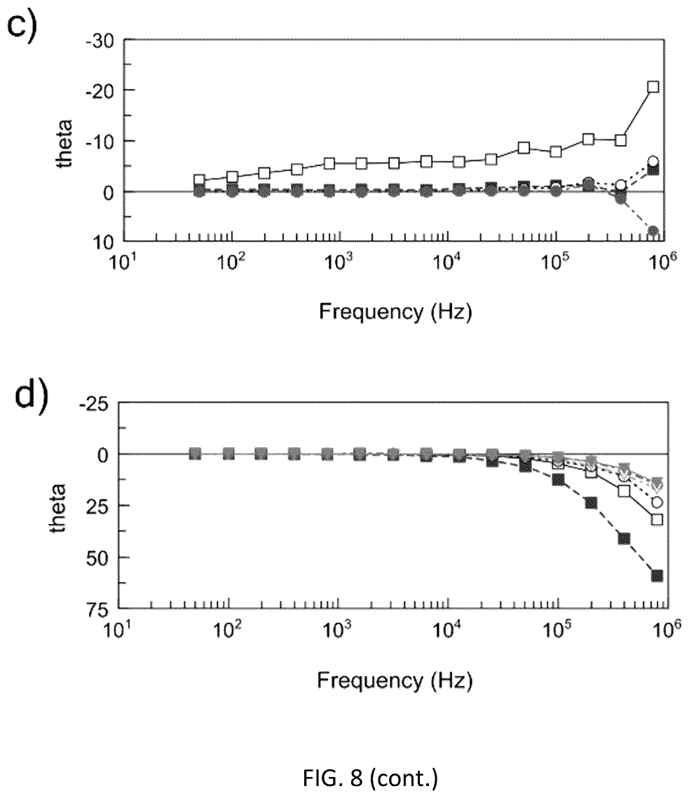

Another method to view EIS measurements involves Bode plots, where the magnitude of the impedance (|Z|=\sqrt{Z′²+Z″²}) and the phase angle of the impedance (θ=Z″/Z′) are plotted as a function of the frequency. It is clear that the impedance of the PEDOT:PSS film with 50% phenylalanine has orders of magnitude smaller impedance than the pure PEDOT:PSS film for the entire frequency range of measurement, see FIG. 6C, and that the magnitudes of the impedance of the films follow the same trend, see FIG. 8, as the one observed during DC measurements. Furthermore, the influence of the capacitive behavior for the pure PEDOT:PSS sample is apparent towards the higher frequency demonstrated by the negative phase angle, and the influence of the inductive behavior of the 50 vol % PEDOT:PSS sample is apparent towards the higher frequency regime signified by the positive phase angle. It is also to be noted that as the concentration of phenylalanine is increased, the phase angle associated with the film impedance reaches zero at higher frequencies, as the capacitive influence due to the charge transport process is reduced, seen in FIG. 8.

These EIS measurements suggest that phenylalanine in the PPP films enhances charge transport efficiency in the system. With increasing concentration of phenylalanine, the effect of capacitance is diminished and it eventually completely disappears suggesting that as the concentration of phenylalanine is increased, a fewer amount of charges aggregate at the interfaces creating the capacitive effect. Eventually, no capacitive phenomenon is recorded suggesting that charge aggregation at the interfaces, such as the interface of the grain boundary or charge trap sites, is completely eliminated. The evolution of two semicircular Nyquist plot into one semicircle suggests that two time-scale charge transport process is reduced into one with the increasing concentration of phenylalanine in the PPP, and with diminishing capacitive processes, the films eventually show purely resistive behavior system with low impedance. It was observed that the PPP film with 30 vol % phenylalanine demonstrates purely resistive behavior (i.e. θ˜0°) for the frequencies all the way over the range of 100 kHz suggesting highly efficient resistive transport in the film. When the concentration of phenylalanine is further increased, a high-frequency inductive tail was observed, as seen in FIG. 7, which appears in the frequency range of 10 kHz or higher, as seen in FIG. 8, but resistive behavior below those frequencies. High-frequency inductive tail is usually attributed to the inductance of wires and electrodes in the measurement system which could also be the case here, partially. However, it was observed that the magnitude of the phase associated with the inductance (i. e., θ>0) at a frequency depends on the films as well. The highest conductivity film with 50 vol % PEDOT:PSS shows inductive behavior even at lower frequencies compared to other films with high-frequency inductance. This suggests that the high-frequency inductive tail that was observed in PPP films is contributed by the charge transport within the films as well.

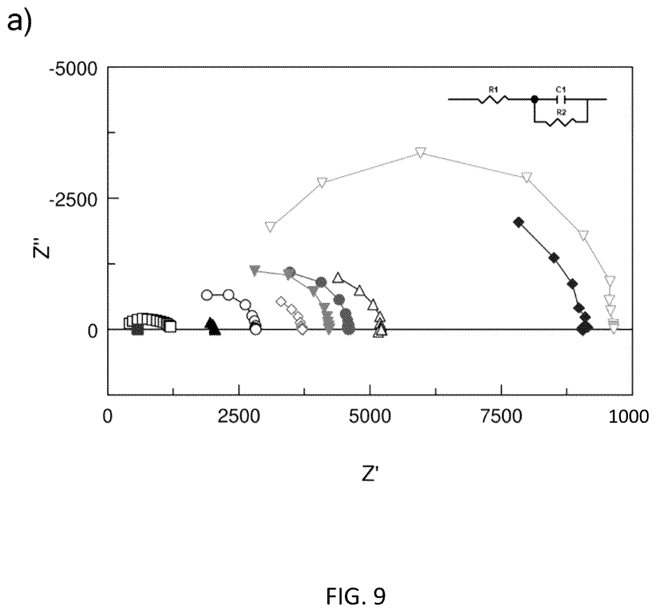

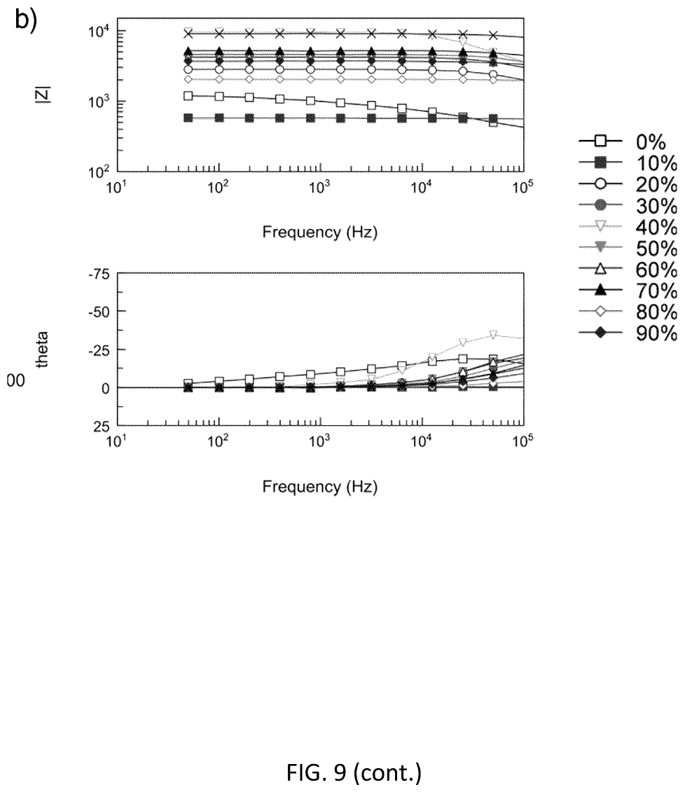

EIS was also carried out for PPA films as well to gain insight into the charge transport mechanism in those films, as seen in FIG. 9. Nyquist plots for PPA film are semicircular that fit Randles circuit with capacitance and resistive components. The magnitude of the impedance follows the same trend as the one observed in the DC measurements. Comparing the EIS Nyquist plots for PPA films with PPP films, it is clear that the presence of phenylalanine in PEDOT:PSS film significantly changes the charge transport mechanism in the film.

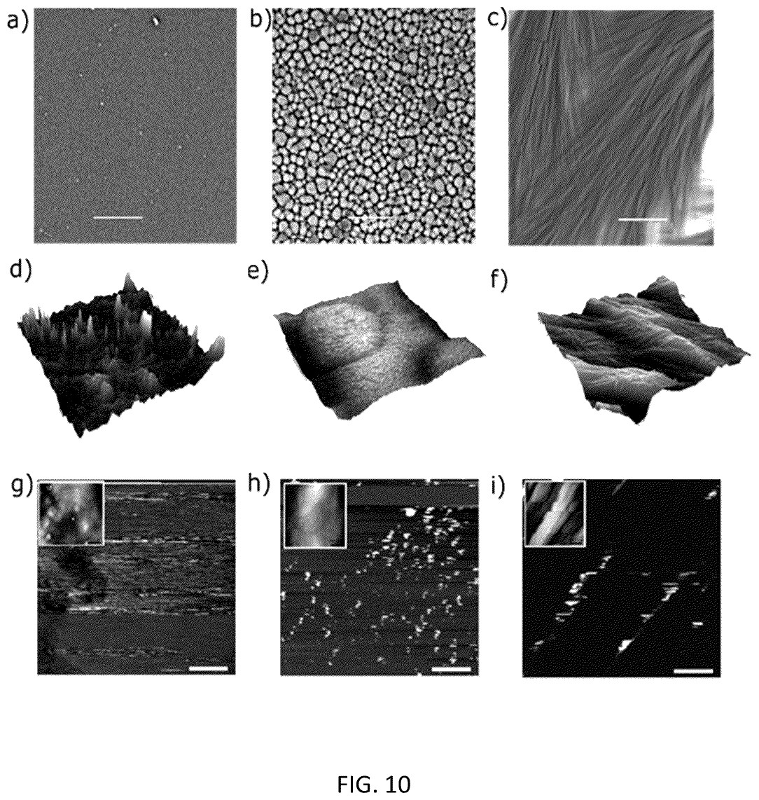

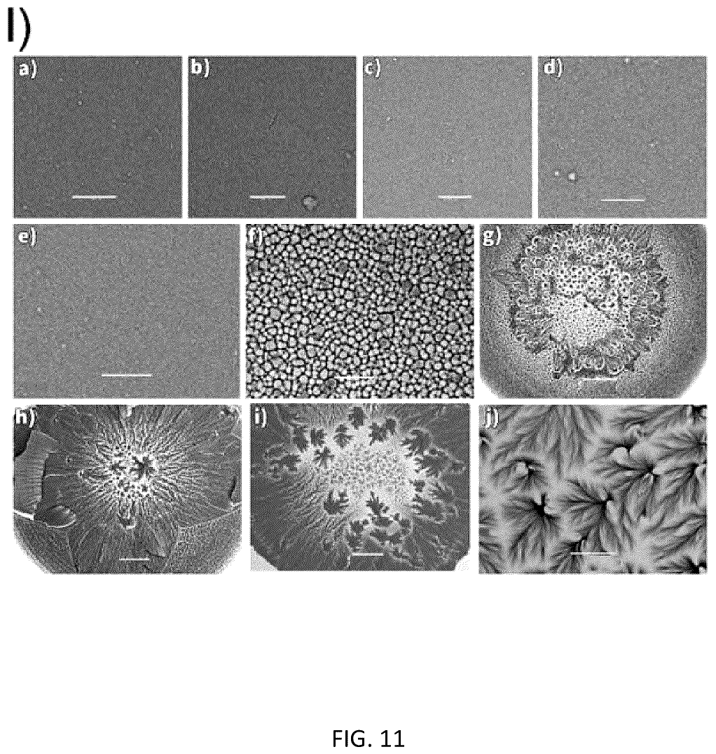

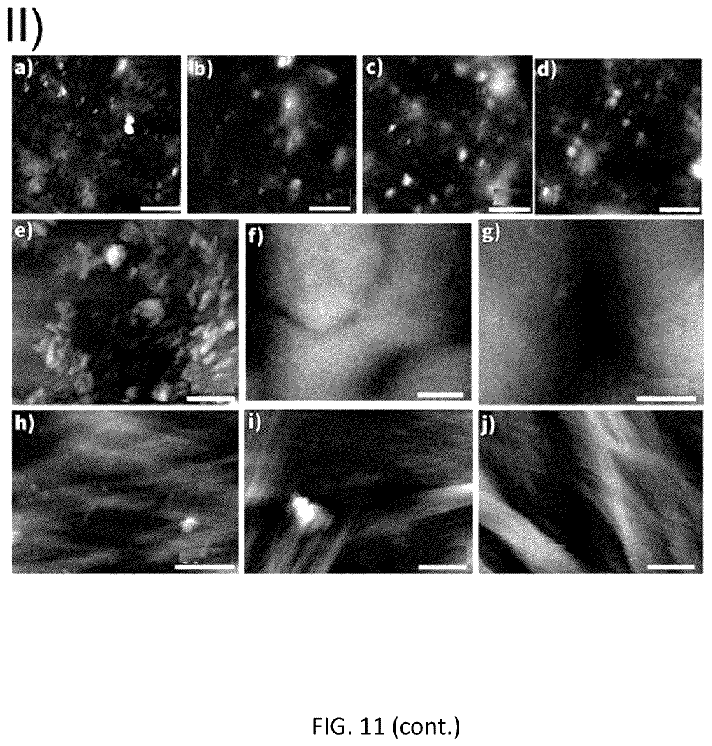

In order to understand if there are any morphological changes in the PPP film with an increasing amount of phenylalanine, the films were observed under an SEM and AFM, a as seen in FIGS. 10 and 11, respectively. PEDOT:PSS film with no phenylalanine is essentially flat with minimal surface features, as seen in FIGS. 10A and 10D. However, when phenylalanine is introduced, globular structures appear which grow in concentration with the increasing concentration of phenylalanine, as seen in FIG. 11. PPP films with 50 vol % phenylalanine have dense globular structures as seen in FIG. 10B (FIG. 5b) with a diameter in the range of about 5 μm, see FIG. 10E (FIG. 5e), distributed throughout the surface. The size of globules are smaller towards the center of the circular films and larger at the edges. The AFM image of this surface shows that the surface is not only composed of the globules but also of self-assembled short phenylalanine fibrils scattered all over the surface. When the concentration of phenylalanine is further increased, the globular surface gives away to hierarchical structures, as seen in FIG. 10, which appear to be structures formed by fusion of the self-assembled fibrillar structures. The surface of PPP films with 90 vol % phenylalanine has this two-dimensional mat spread created by the alignment of multiple phenylalanine fibrils, as seen in FIGS. 10C and 10F.

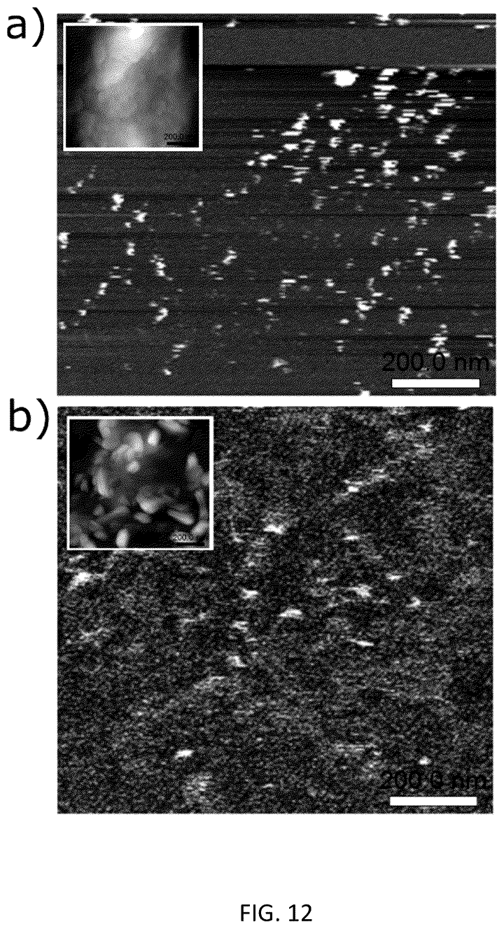

Conducting probe AFM (CP-AFM) were carried out to acquire the current map on the film surfaces, as seen in FIG. 10G through 10I. The PEDOT:PSS film did not demonstrate any features in terms of the current profile on the surface. However, when the measurements were carried out for 50% phenylalanine film, conducting spots were observed to be distributed on the surface, especially on top of the globules. The distribution of the conducting spots was thinner when the current in regions between globules we mapped, see FIG. 12, indicating that the globules are the regions rich in PEDOT. In 90 vol % samples, it was observed that the fibril-like structures of phenylalanine are non-conducting, but the edges of those fibrils are conducting possibly due to PEDOT being around the edges.

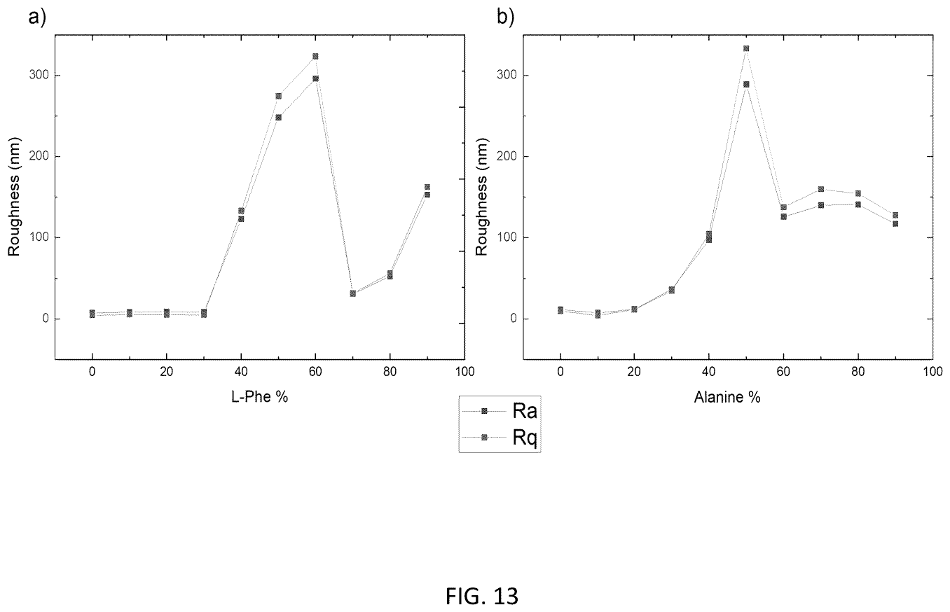

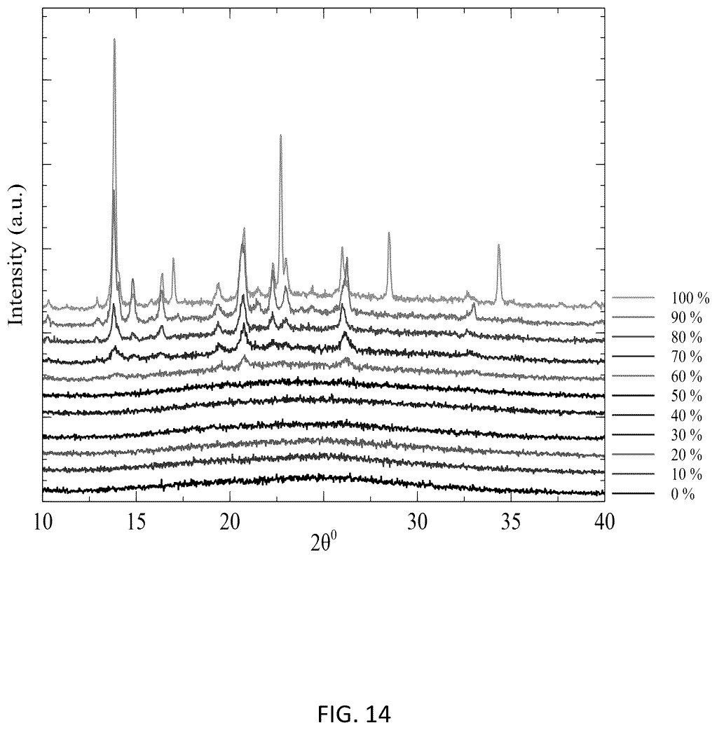

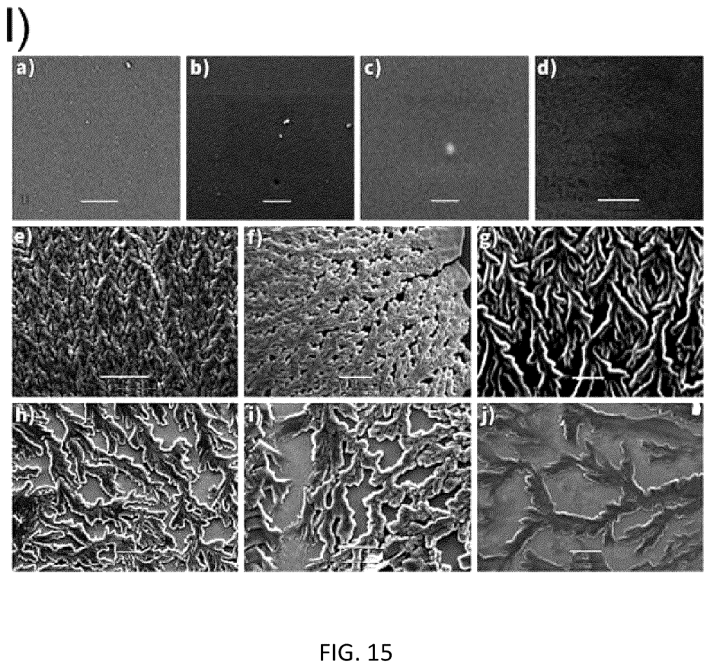

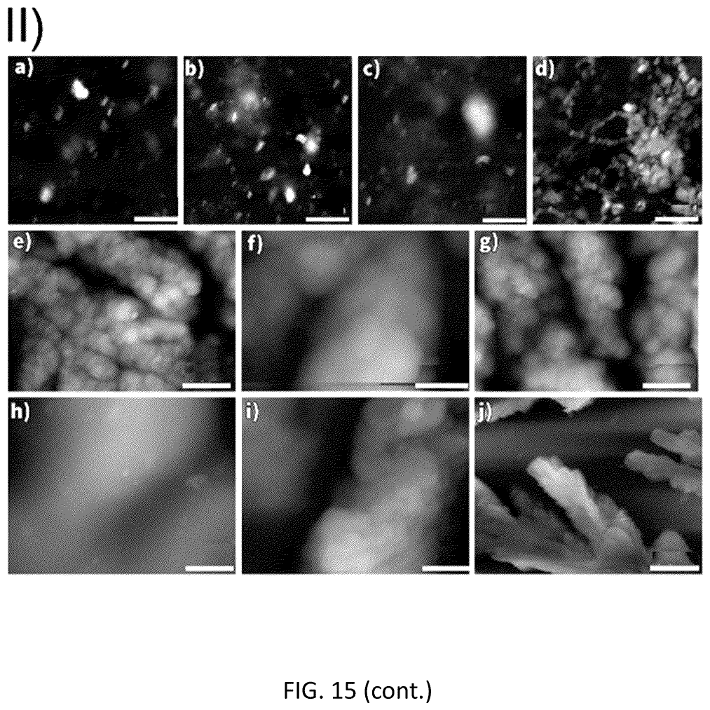

These observations suggest that there are two different mechanisms of self-assembly involved in PPP films. The first mechanism involves the appearance and growth of the globules on the film surface as phenylalanine concentration is increased in PPP films. The second mechanism involves the formation of elongated fibrils of phenylalanine fused with neighboring fibrils to create mat-like structures on the surface. Using the topographical images from AFM, the roughness of the surface of PPP films was calculated as seen in FIG. 13, which also demonstrates these two processes on the film. The evolution of the surface roughness parameters seen in FIG. 13 shares some similarity with the evolution of the conductivity of the film seen in FIG. 4, suggesting that the structural changes in the PPP films due to phenylalanine possibly plays a significant role in enhancing charge transport through the PPP films. XRD measurements were carried on these films, as seen in FIG. 15 (Fig. S9), to get further insight into the structure of the films. Despite adding some phenylalanine to PEDOT:PSS, no differences were seen in the spectra of PPP films with PEDOT:PSS until the concentration of the phenylalanine is higher than the concentration of PEDOT:PSS. This suggests that the globular structures that appear on the surface of the PPP films are not atomically crystalline. The films show crystallinity only after the concentration of the phenylalanine exceeds that of PEDOT:PSS which, based on the images in FIG. 2, appears to be due to a significant accumulation of phenylalanine structures on the film surface.

Based on the conduction behavior of the PPP films and morphological changes observed in them, it is proposed that the PEDOT:PSS undergoes phase change with the introduction of phenylalanine. Based on the observation that 1) conductivity of PPP films increases exponentially when the concentration of phenylalanine is increased from none to 50 vol %, 2) capacitive component in the charge transport process decreases with the increasing amount of phenylalanine, and 3) conducting globular structures appear on the surface which increases in size with the increasing concentration of phenylalanine in PPP films, that the introduction of phenylalanine likely promotes the growth of PEDOT:PSS domains and hence reduces the amount of PSS in between the domain and thus help create more efficient charge transport paths within the films.

There have been other reports of the formation of the globules on the surface of PEDOT:PSS films when they are doped with secondary dopants which enhanced the conductivity of the films. For example, when ethylene glycol (EG) was introduced as a dopant in PEDOT:PSS, globular cluster domains are population on the surface of the film which was quantified by the surface roughness and the current map which increase in size with an increasing amount of dopant. Similar morphological phenomenon has also been reported while doping PEDOT:PSS with dimethyl sulfoxide (DMSO). And, it appears that similar morphological changes occur in PEDOT:PSS films when phenylalanine is introduced. Morphological changes occur in PPA films as well with the increasing amount of alanine, but the surface structures are not globular, as seen in FIG. 15. In the PPA with 50 vol % alanine solution, hierarchical structures appear on the surface due to aggregation of alanine, but the lack of PEDOT-rich globular structure means that the film does not allow for efficient charge transport as in the case of PPP films.

It is known that the polarity of dopant also affects the conductivity in PEDOT:PSS films by screening charges and hence limiting interaction between PEDOT and PSS and inducing phase separation. Such charge screening and phase separation can also be caused by the introduction of zwitterions in the PEDOT:PSS solution. However, both alanine and phenylalanine have non-polar residues and are zwitterions with similar isoelectric points of 6 and 5.48, respectively. Therefore, the charge interaction between amino acid and PEDOT:PSS probably is not the reason that morphological changes occur in PPP and PPA films with different conduction mechanism. The major difference between these two amino acids is the presence of aromatic amino acid residue in phenylalanine and lack of it in alanine, which also makes phenylalanine highly hydrophobic. It could be that the hydrophobicity of this residue is responsible for bringing about the morphological changes in the film during the self-assembly process in the PEDOT:PSS—phenylalanine solution mixture. At this point, it is unclear if the aromatic residues in phenylalanine also contribute as sites for charge transport, especially in the PPP films with a low concentrations of phenylalanine. Nevertheless, the fact that the essential amino acid such as phenylalanine can assist with dramatic enhancement of charge transport through PEDOT:PSS system is a significant advancement in integrating biological molecules in electronics.

The conductivity of PEDOT:PSS films can significantly be raised by the addition of phenylalanine. At the 50 vol % combinations of PEDOT:PSS solution and phenylalanine solution, we were able to record the conductivity of about 600 S/cm compared to the conductivity of 1.5 S/cm for pristine PEDOT:PSS film. According to EIS measurements, this increase in conductivity is accompanied by more efficient charge transport through the film with diminishing capacitive components which eventually ceases as the film's conductivity increases by orders of magnitude with an increasing amount of phenylalanine. SEM and AFM imaging demonstrate that this coincides with the appearance of micrometer size globular structures on the film surface which, according to CP-AFM, are conducting clusters potentially rich in PEDOT. Therefore, the efficient charge transport through the film is possibly due to the formation of larger PEDOT granular domains with decreasing amount of the PSS between grains to impede charge transport. The prospect of using biological materials such as amino acids as dopants to improve the conductivity of PEDOT:PSS which is used to construct biocompatible electrodes and devices opens up opportunities in bioelectronics and at the same time helps realize electronics based on sustainable sources.

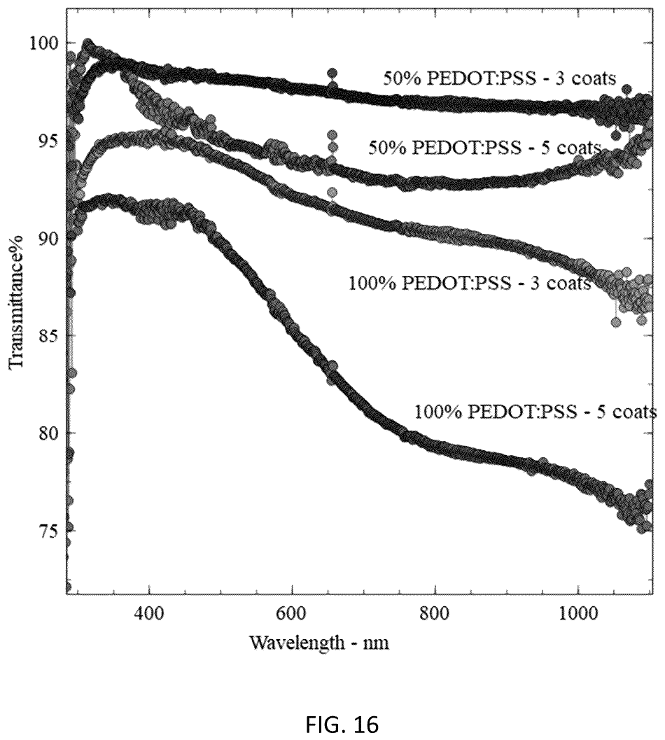

Another desirable feature of films according to the present invention is transmittance, i.e., the ability of the film to allow the light to transmit through it. Thin films of PEDOT:PSS are often used as a transparent conductive electrode. Transparent conductive electrodes are useful for applications in vertical devices, such as photovoltaic cells and touch screens, where the light needs to pass through the conducting electrode layer. Introducing phenylalanine improves the transmittance of PEDOT:PSS films (FIG. 16). The transmittance of composite thin films with 50 vol % PEDOT:PSS and 50 vol % phenylalanine higher was higher than the transmittance of thin films of 100 vol % PEDOT:PSS when the same number of coatings were applied. Interestingly, when five coatings of thin films are applied, the transmittance of PEDOT:PSS diminishes, but the composite film still stays highly transparent.

Therefore, the use of the essential biomolecule phenylalanine as a dopant that can help improve both the conductivity and transmittance of the PEDOT:PSS films is a unique discovery with potential applications in organic electronics and bioelectronics.

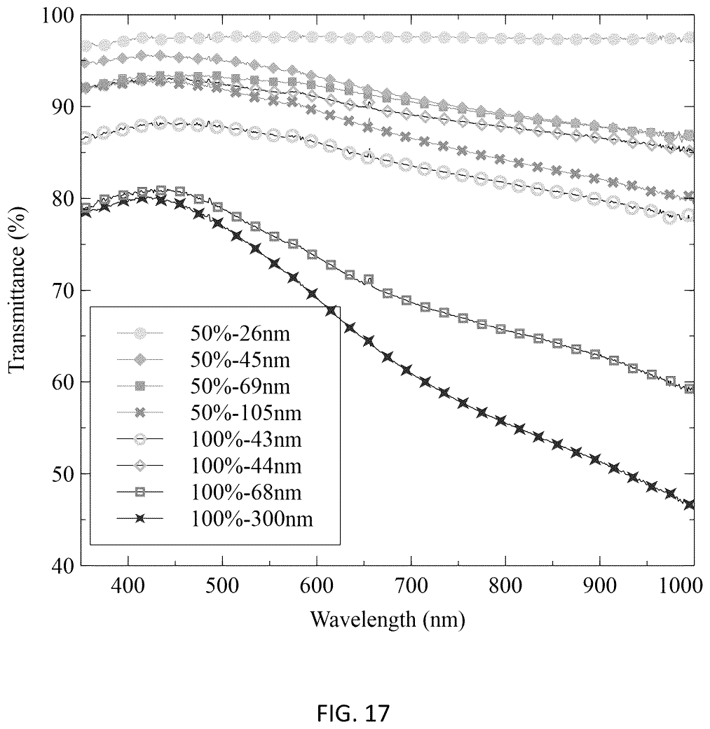

Referring to FIG. 17, the transmittance of films with 100% PEDOT:PSS of various nanometer scale thicknesses treated with methanol compared to films with 50 vol % phenylalanine solution and 50 vol % PEDOT:PSS solution, also treated with methanol, demonstrate that the transmittance was significantly more for the thin films films with phenylalanine.

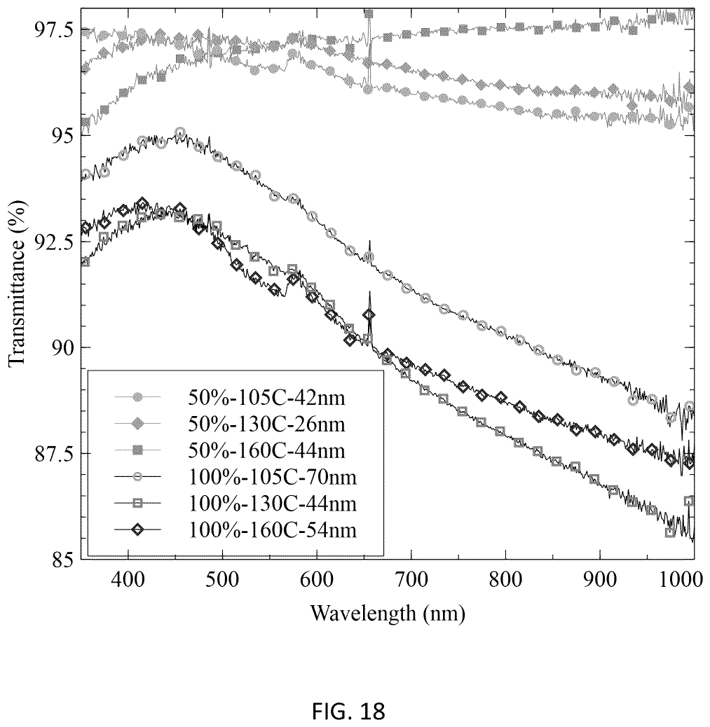

Referring to FIG. 18, the transmittance of the films with 100% PEDOT:PSS of various nanometer scale thicknesses compared to the films with 50 vol % phenylalanine solution and 50 vol % PEDOT:PSS solution, both of which were annealed after methanol treatment, demonstrate that annealing the films increases the transmittance of the films overall, but the amount of increase was significantly more for the films with 50 vol % phenylalanine.

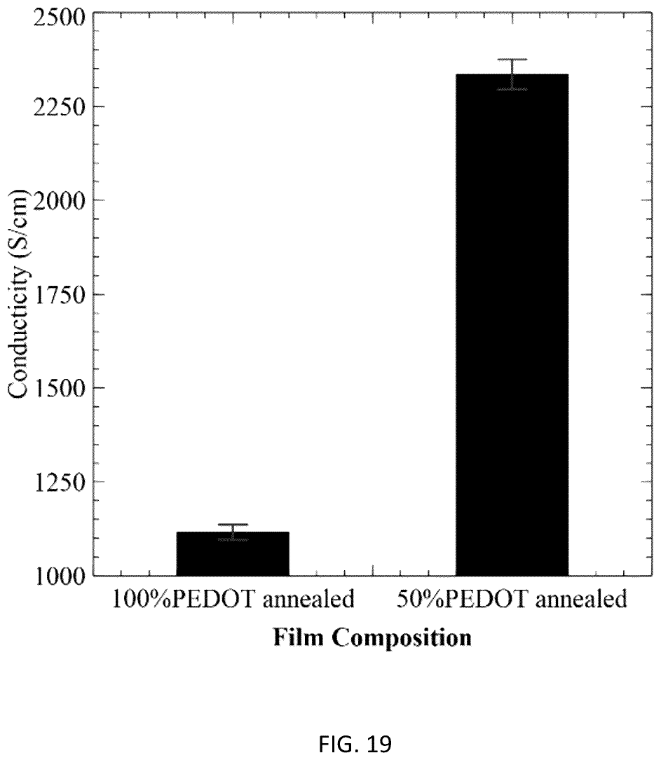

Referring to FIG. 19, treating PEDOT:PSS films with methanol and then annealing significantly improves conductivity (from ˜1 S/cm mentioned by the supplier for PEDOT:PSS increased to more than 1000 S/cm) of the film as reported elsewhere. However, introducing 50 vol % phenylalanine solution in the PEDOT:PSS film and treating it with methanol and annealing improves the conductivity even more (by a factor of 2 compared to similarly prepared film of 100% PEDOT:PSS).

### Example

### Materials

L-phenylalanine (99%) and L-alanine (99%) was purchased from Fisher Scientific, and 1.3% Poly(3,4-ethylenedioxythiophene)-poly(styrenesulfonate) PEDOT:PSS solution from Millipore Sigma. Thin-film Gold Interdigitated Array Microelectrodes (10/10 μm) (ED-IDA1-Au) were purchased from Micrux Technologies.

### Preparing Composite Films:

0.17 mg of the L-Phe per 1 mL of deionized water was added in a microcentrifuge tube and stirred with a Fisherbrand Digital Vortex Meter at 3000 rpm for 30 seconds, until most of the solid was dissolved. After letting it settle for 5 minutes, the phenylalanine solution was mixed with PEDOT:PSS solution with to create phenylalanine-PEDOT:PSS composite with various volumetric percentages of the constituent solution. A stock solution of 150 ml was created with the volumetric percentage of L-Phe solution ranging from 0% to 100% and PEDOT:PSS solution ranging from 100% to 0%. These mixtures were mixed for 60 seconds at 3000 rpm and stored in at 5° C. For creating dropcast films, 3 μL of the solution was drop-cast onto the interdigitated electrodes. After letting it dry for 24 hours, this resulted in an approximately circular spot with a mean area of 6.497+−0.42 mm², which was calculated using ImageJ. The same procedure was repeated for composite films with alanine. Thin films were fabricated by covering a 1×1″ microscope slide glass with 300 μL of the solution and spin coated. Spin coating was carried out by first spinning the sample at 300 rpm for 4 seconds followed by 2000 rpm for 50 seconds to create thin films with thickness in the range of tens of nanometers. For methanol treatment, the spin coated sample was placed on a hot plate at 130° C. for 15 minutes in the fume hood followed by dropcasting 100 microliters of methanol onto the film. Annealed films were created by heating the methanol treated sample again at 130° C. for 15 minutes. The 50 vol % methanol treated film was prepared in the same manner. For multiple coatings, this process was repeated for each coating cycle.

### Conductivity Measurements

The DC electrical measurements were carried out with a Keithley SMU 2612B connected to a probe station (TS150, MPI Corp.) with the help of Keithley Kickstart software to control the control SMU. AC electrical measurements were carried out with Reference 620+ potentiometer (Gamry Instruments) connected to the same probe station. The potentiometer was controlled by Echem Analyst (Gamry) software to set parameters for electrochemical impedance spectroscopy (EIS) measurements. EIS data analysis and modeling were carried out with ZView 4.0 software (Scribner Associates). All electrical measurements were carried out at room temperature and humidity.

The solutions with varying volumetric mixtures were drop-cast on interdigitated electrodes (Micrux Technologies, ED-IDA1-Au) with 10 μm pitch and 10 μm wide gold electrode on glass substrate. For conductivity measurements, the film thickness was measured by P7 Stylus Profilometer (KLA Tencor) or NewView 7300 Optical Profilometer (Zygo) whenever appropriate. After calculating conductance (G) values from the IV curves, the conductivity (6) values were calculated using the equation: 6=GL/A where L is the electrode gap and A is the film thickness.

JEOL (JM6360LV) Scanning Electron Microscope (SEM) was used for observing the surface of the composite films. For SEM imaging, 5 μL of the mixture solution was drop-cast onto silicon dioxide substrate. Samples were left out for 24 hours before taking SEM images. The SEM images were taken in BEC mode, with 20 V as the accelerating voltage.

### X-Ray Spectroscopy

X-ray diffraction (XRD) was carried out on Philips PW3040 X-ray diffractometer with X′Pert software for extracting data. The instrument uses Cu Kα radiation with wavelength of 1.54 Å. The 20 mg/ml solution of self-assembled fibrils was drop cast on glass slides and left to dry overnight. The XRD setup involved 0.040 soller slit, 10 divergence, 10 anti-scatter slits, and 1/40 receiving slit.

### AFM Studies

AFM imaging of the sample surface was carried out using a Bruker Dimension Icon AFM in ScanAsyst mode with SCANASYST-AIR probes which are also manufactured by Bruker.

Conducting-probe AFM (CP-AFM) was carried out by using the Bruker Dimension Icon AFM in PF-TUNA mode with PFTUNA probes coated with Pt/Ir. For the measurements, we prepared the samples by drop-casting 5 μl of the mixture solutions on gold-plated silicon dioxide chips as substrates. 1V bias was applied to the substrate while the current mapping was carried out over the surface.

What is claimed is:

1. A composite film, comprising:
an amount of phenylalanine; and
an amount of poly(3,4-ethylenedioxythiophene) doped polystyrene sulfonate (PEDOT:PSS).

2. The composite film of claim 1, wherein the amount of phenylalanine comprises between 10 and 90 percent by volume of the composite film.

3. The composite film of claim 1, wherein the amount of phenylalanine comprises 50 percent by volume of the composite film.

4. The composite film of claim 1, wherein the composite film is characterized by a conductivity of over 500 siemens per centimeter.

5. The composite film of claim 1, wherein the composite film has an optical transmissivity that is greater than a film consisting of poly(3,4-ethylenedioxythiophene) doped polystyrene sulfonate.

6. The composite film of claim 1, wherein the film has been treated with methanol.

7. The composite film of claim 7, wherein the film has been annealed.

8. A method of making a composite film, comprising the step of drop casting a solution comprising an amount of poly(3,4-ethylenedioxythiophene) doped polystyrene sulfonate (PEDOT:PSS) and an amount of phenylalanine.

9. The method of claim 8, wherein the amount of phenylalanine comprises between 10 and 90 percent by volume of the composite film.

10. The method of claim 8, wherein the amount of phenylalanine comprises 50 percent by volume of the composite film.

11. The method of claim 8, wherein the composite film is characterized by a conductivity of over 500 siemens per centimeter.

12. The method of claim 8, wherein the composite film has an optical transmissivity that is greater than a film consisting of poly(3,4-ethylenedioxythiophene) doped polystyrene sulfonate.

13. The method of claim 8, further comprising the step of treating the film with methanol.

14. The method of claim 13, further comprising the step of annealing the film after the step of treating the film with methanol.
